(19) United States
(12) Patent Application Publication
(10) Pub. No.: US 2004/0233625 A1
(43) Pub. Date: Nov. 25, 2004

(54) Adapter for mobile wireless communication device, mobile wireless communication device and method for selectively mounting adapter for mobile wireless communication device

(75) Inventors: Takeshi Saitou, Naka (JP); Masaki Uesugi, Hitachinaka (JP); Takashi Tobita, Mito (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hitachi, Ltd., Tokyo (JP)

(21) Appl. No.: 10/787,502

(22) Filed: Feb. 25, 2004

(30) Foreign Application Priority Data
Feb. 28, 2003 (JP) 2003-052494

(51) Int. Cl. H05K 5/00

(52) U.S. Cl. 361/683

(57) ABSTRACT

An adapter for mounting an optionally-additional functional component onto a mobile wireless communication device (on which a battery for electrically energizing the mobile wireless communication device is mountable), comprises a joint portion connectable to the mobile wireless communication device so that the adapter is attached through the joint portion to the mobile wireless communication device in a removable manner, and a component holding portion adapted to hold the optionally-additional functional component on the component holding portion.

### BACKGROUND OF THE INVENTION

The present invention relates to a mobile wireless communication device, an adapter for the mobile wireless communication device, and a method for selectively mounting the adapter for the mobile wireless communication device.

In a prior art mobile wireless communication device as disclosed by JP-A-10-145470, an external memory medium can be inserted into the mobile wireless communication device body so that the external memory medium is electrically connected to the mobile wireless communication device body to apply an audio function to the mobile wireless communication device.

### SUMMARY OF THE INVENTION

An object of the present invention is to provide a mobile wireless communication device, an adapter for the mobile wireless communication device, and a method for selectively mounting the adapter for the mobile wireless communication device, in which an optionally-additional function can be easily and smartly applied to the mobile wireless communication device.

According to the present invention, an adapter for mounting an optionally-additional functional component onto a mobile wireless communication device (on which a battery for electrically energizing the mobile wireless communication device is mountable), comprises, a joint portion connectable to the mobile wireless communication device so that the adapter is attached through the joint portion to the mobile wireless communication device in a removable manner, and a component holding portion adapted to hold the optionally-additional functional component on the component holding portion. Since the joint portion is connectable to the mobile wireless communication device so that the adapter is attached through the joint portion to the mobile wireless communication device in a removable manner, and a component holding portion can hold the optionally-additional functional component on the component holding portion, an optionally-additional function carried out by the optionally-additional functional component can be easily and smartly applied to the mobile wireless communication device.

The optionally-additional functional component may include at least one of a suction cup, a clip, a photograph holder and a game box. The optionally-additional functional component may include an electric component to be electrically connected to the mobile wireless communication device. The optionally-additional functional component may be securely fixed to the component holding portion as a part of the adapter. The optionally-additional functional component may be connectable to the adapter so that the optionally-additional functional component is held on the component holding portion in a removable manner. The optionally-additional functional component may include at least one of an electronic memory device, a tuner electric circuit, a wireless communication electric circuit, an antenna, a camera and a loudspeaker.

If a battery for electrically energizing the mobile wireless communication device is mountable on the mobile wireless communication device, and at least a part of the battery is mountable between the adapter and the mobile wireless communication device as seen in a view direction perpendicular to a stacking direction in which the adapter and the mobile wireless communication device are stacked so that the adapter is usable as a cover covering the at least a part of the battery in the stacking direction, a thickness of a combination of the adapter and the mobile wireless communication device in the stacking direction is mininized.

If at least a part of the battery is mountable between the optionally-additional functional component and the mobile wireless communication device as seen in a view direction perpendicular to a stacking direction in which the adapter and the mobile wireless communication device are stacked so that the optionally-additional functional component is usable as a cover covering the at least a part of the battery in the stacking direction, the optionally-additional functional component can extend over the at least a part of the battery to utilize effectively a space over the battery.

If the component holding portion can hold the optionally-additional functional component in such a manner that the optionally-additional functional component is mountable between the adapter and the mobile wireless communication device as seen in a view direction perpendicular to a stacking direction in which the adapter and the mobile wireless communication device are stacked so that the adapter is usable as a cover covering the optionally-additional functional component in the stacking direction, the optionally-additional functional component can be protected by the adapter.

An electrically conductive contact terminal surface of the adapter may be electrically connectable to the electric component and contactable the mobile wireless communication device so that the electric component is electrically connected through the electrically conductive terminal contact surface to the mobile wireless communication device in a separable manner. If at least a part of the battery is mountable between the adapter and the mobile wireless communication device as seen in a view direction perpendicular to a stacking direction in which the adapter and the mobile wireless communication device are stacked so that the adapter is usable as a cover covering the at least a part of the battery in the stacking direction, and the electrically conductive contact terminal surface is arranged to be prevented from overlapping the battery as seen in the stacking direction, the battery is prevented from interfering with an electric connection between the adapter and the mobile communication device through the electrically conductive contact terminal surface. If the at least a part of the battery is mountable between the optionally-additional functional component and the mobile wireless communication device as seen in a view direction perpendicular to a stacking direction in which the adapter and the mobile wireless communication device are stacked so that the optionally-additional functional component is usable as a cover covering the at least a part of the battery in the stacking direction, and the electrically conductive contact terminal surface is arranged to be prevented from overlapping the battery as seen in the stacking direction, the battery is prevented from interfering with an electric connection between the optionally-additional functional component and the mobile communication device through the electrically conductive contact terminal surface.

The mobile wireless communication device may comprises an adapter for mounting an optionally-additional functional component onto the mobile wireless communication device, including, a joint portion connectable to the mobile wireless communication device so that the adapter is attached through the joint portion to the mobile wireless communication device in a removable manner, and a component holding portion adapted to hold the optionally-additional functional component on the component holding portion.

The mobile wireless communication device on which an adapter including an adapter joint portion connectable to the mobile wireless communication device and a component holding portion adapted to hold a optionally-additional functional component on the component holding portion is mountable, may comprise a device joint portion connectable to the adapter joint portion so that the adapter is attached through the adapter and device joint portions to the mobile wireless communication device in a removable manner.

A method for selectively mounting onto a mobile wireless communication device an adapter being connectable to the mobile wireless communication device so that the adapter is attached to the mobile wireless communication device in a removable manner and including a component holding portion adapted to hold a optionally-additional functional component on the component holding portion, comprises the steps of preparing a plurality of the adapters, selecting one of the adapters, and mounting the selected one of the adapters onto the mobile wireless communication device.

Other objects, features and advantages of the invention will become apparent from the following description of the embodiments of the invention taken in conjunction with the accompanying drawings.

### BRIEF DESCRIPTION OF THE SEVERAL VIEWS OF THE DRAWINGS

FIG. 1 is a schematic oblique projection front view showing a mobile wireless communication device as an embodiment of the invention.

FIG. 2 is a schematic oblique projection back view showing the mobile wireless communication device shown in FIG. 1 with a detachable cover covering a battery containing portion of a device casing.

FIG. 3 is a schematic oblique projection back view showing the mobile wireless communication device shown in FIG. 1 with a detachable cover covering a battery containing portion of a device casing and receiving an optionally-additional functional component on an inside of the cover.

FIG. 4 is a schematic oblique projection exploded back view showing the mobile wireless communication device from which the detachable cover without the optionally-additional functional component or the detachable cover with the optionally-additional functional component is detached.

FIG. 5 is a schematic oblique projection back view showing the detachable cover without the optionally-additional functional component.

FIG. 6 is an enlarged cross sectional view taken along line VI-VI in FIG. 2.

FIG. 7 is an enlarged cross sectional view taken along line VII-VII in FIG. 2.

FIG. 8 is an enlarged cross sectional view of a portion VIII in FIG. 7.

FIG. 9 is a schematic oblique projection back view showing the detachable cover as a adapter with the optionally-additional functional component.

FIG. 10 is a schematic oblique projection exploded back view showing the detachable cover or adapter with the optionally-additional functional component.

FIG. 11 is an enlarged cross sectional view taken along line XI-XI in FIG. 3.

FIG. 12 is an enlarged cross sectional view taken along line XII-XII in FIG. 3.

FIG. 13 is an enlarged cross sectional view of a portion XIII in FIG. 12.

FIG. 14 is a schematic oblique projection exploded back view showing a first embodiment of adapter for mobile wireless communication device on which adapter a memory card of the optionally-additional functional component as shown in FIGS. 3, 9 and 10 is detachably mounted.

FIG. 15 is a schematic oblique projection exploded back view showing a second embodiment of adapter for mobile wireless communication device on which adapter an electric circuit module of the optionally-additional functional component including a tuner circuit is detachably mounted.

FIG. 16 is a schematic oblique projection exploded back view showing a third embodiment of adapter for mobile wireless communication device on which adapter an electric circuit module of the optionally-additional functional component including a wireless communication circuit is detachably mounted.

FIG. 17 is a schematic oblique projection exploded back view showing a fourth embodiment of adapter for mobile wireless communication device on which adapter an antenna module of the optionally-additional functional component including an antenna is detachably mounted.

FIG. 18 is a schematic oblique projection exploded back view showing a fifth embodiment of adapter for mobile wireless communication device on which adapter a camera module of the optionally-additional functional component including a camera is detachably mounted.

FIG. 19 is a schematic oblique projection exploded back view showing a sixth embodiment of adapter for mobile wireless communication device on which adapter a loudspeaker module of the optionally-additional functional component including a loudspeaker is detachably mounted.

FIG. 20 is a schematic oblique projection front view showing a seventh embodiment of adapter for mobile wireless communication device on which adapter a non-electric component of the optionally-additional functional component including a suction cup is detachably mounted.

FIG. 21 is a schematic oblique projection front view showing an eighth embodiment of adapter for mobile wireless communication device on which adapter a non-electric component of the optionally-additional functional component including a hand grip shape is detachably mounted.

FIG. 22 is a schematic oblique projection front view showing a nineth embodiment of adapter for mobile wireless communication device on which adapter a non-electric component of the optionally-additional functional component including a photograph holder is detachably mounted.

FIG. 23 is a schematic oblique projection front view showing a ninth embodiment of adapter for mobile wireless communication device on which adapter a non-electric component of the optionally-additional functional component including an embedded game box is detachably mounted.

FIG. 24 is a diagram showing an electric circuit between the mobile wireless communication device and the optionally-additional functional component.

### DESCRIPTION OF THE PREFERRED EMBODIMENTS

Although foldaway mobile wireless communication devices or telephones are described below, the invention is applicable to non-foldaway or straight-type mobile wireless communication devices or telephones.

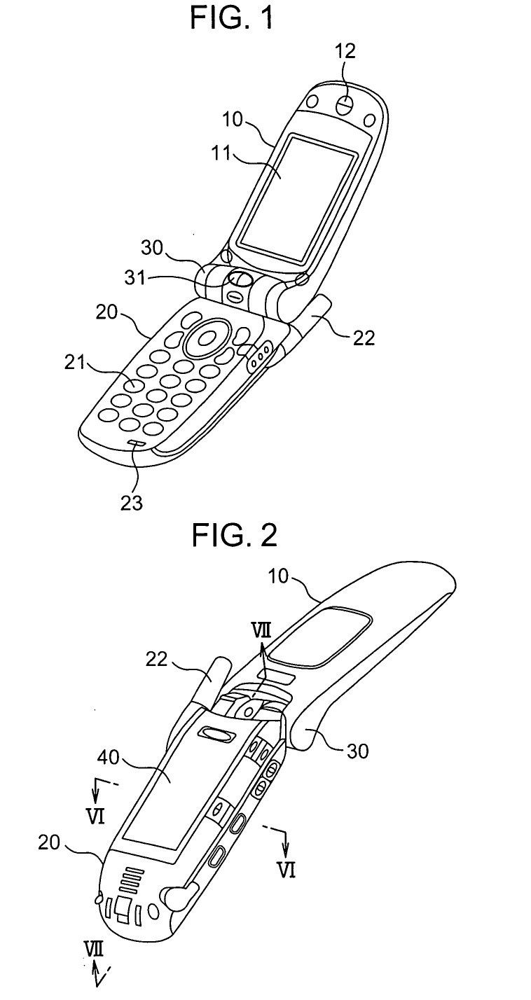

As shown in FIG. 1, a foldaway mobile phone has first and second casing 10 and 20 whose ends form a swingable hinge 30 so that the first casing 10 can be opened and closed with respect to the second casing. When the first casing 10 is opened, the mobile phone is operable.

An indicating part 11 is provided with the first casing 10, and operation keys 21 and an antenna 22 are provided with the second casing 20 so that a wireless communication is received through the antenna 22 by operating the operation keys 21 and contents of the wireless communication is shown on the indicating part 11.

Further, a receiver 12 is provided with the first casing 10 to hear the contents of the wireless communication.

A microphone 23 is provided with the second casing 20 to send signals of spoken contents through the antenna 22 to another mobile phone.

A camera 31b is provided with the hinge 30 so a that taken photograph is stored in an internal memory to be displayed on the indication part 11 and to be send through the antenna 22 to the another mobile phone.

As shown in FIG. 2, the second casing 20 has a battery containing portion at a reverse side thereof and a detachable cover 40 covers the battery containing portion.

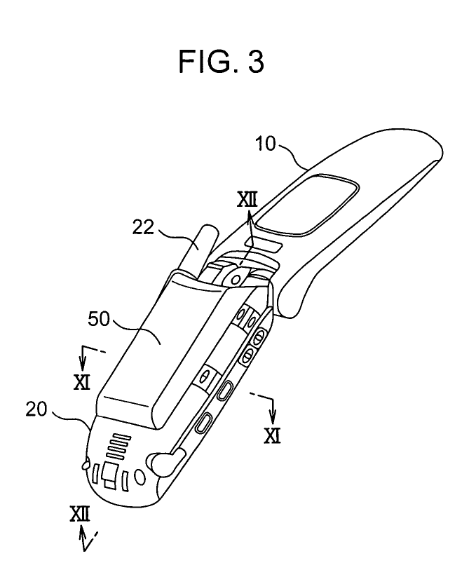

As shown in FIG. 3, an adapter 50 with an optionally additional functional component for the mobile phone provided with a reverse side of the adapter 50 covers the battery containing portion of the second casing 20.

The battery cover 40 as shown in FIG. 2 and the adapter 50 for the mobile phone as shown in FIG. 3 is mounted on the mobile phone shown in FIGS. 1-3 in a removable manner.

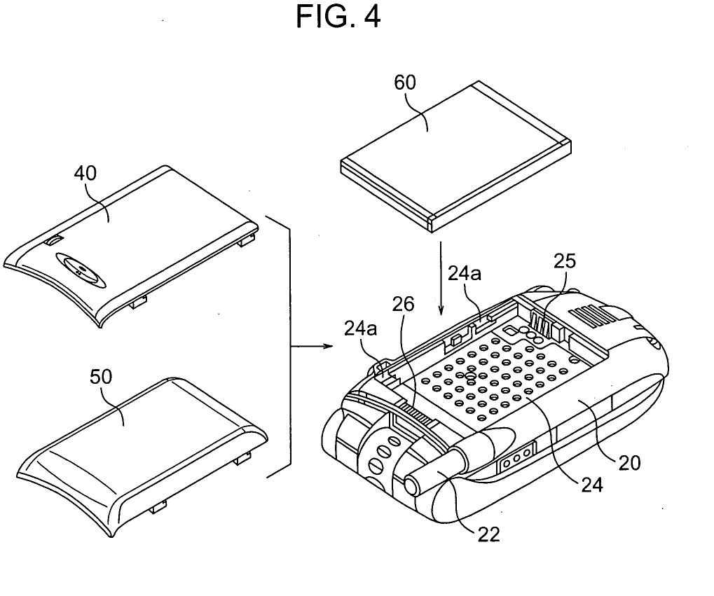

As shown in FIG. 4, a battery containing portion 24 of the second casing 20 has a battery connector 25 to be electrically connected to electric terminal contacts of the battery 60 inserted into the battery containing portion 24. The second casing 20 has a phone body side connector 26 to be electrically connected to an adapter side connector electrically connected to the electric component of the optionally additional functional component mounted on the reverse side of the adapter 50. Therefore, when the adapter 50 is mounted on the battery containing portion 24 of the second casing 20, the electric component of the optionally additional functional component is automatically electrically connected to the phone body side connector 26.

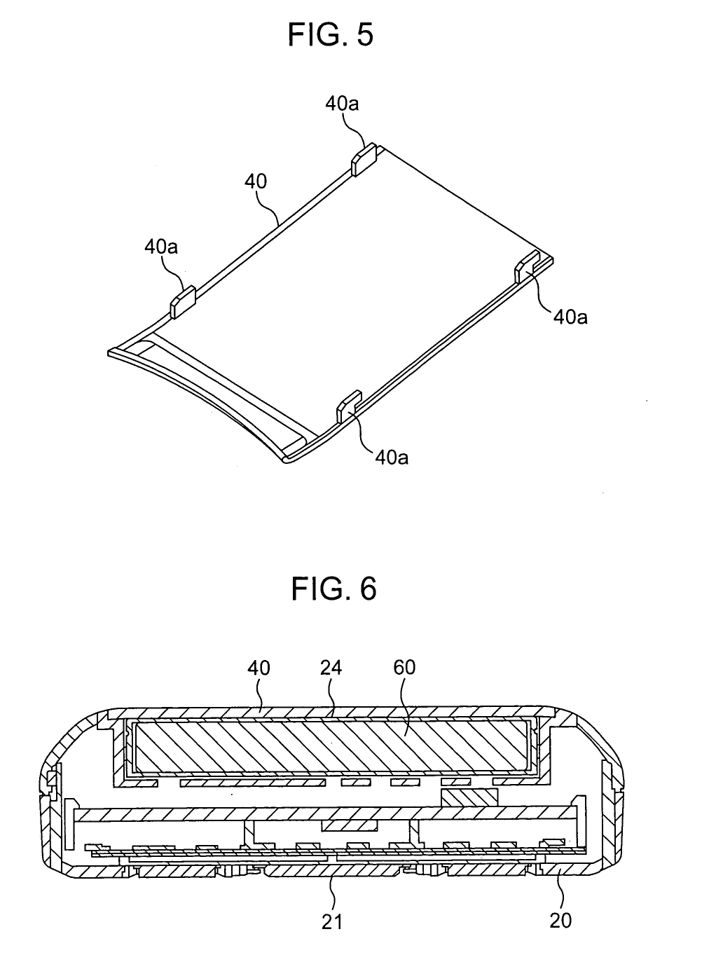

As shown in FIG. 5, cover engaging portions 40a are provided with the battery cover 40 to engage with engage portions of the battery containing portion 24a when the battery cover 40 is mounted on the battery containing portion 24 as shown in FIG. 4. Each of the engaging portions 40a and corresponding one of the engaging portions 24a are engaged with each other to fix the battery cover 40 as shown in FIG. 2, by moving the battery cover 40 downward to contact the casing 20 in FIG. 4, and subsequently moving rightward the battery cover 40 in FIG. 4.

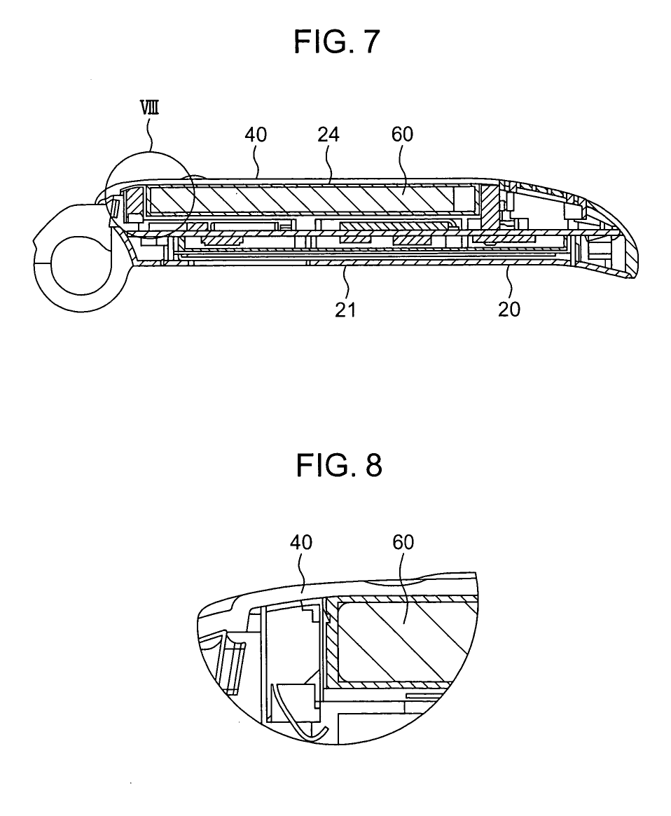

As shown in FIGS. 6-8, the battery cover 40 covers a battery 60 contained by the battery containing portion 24.

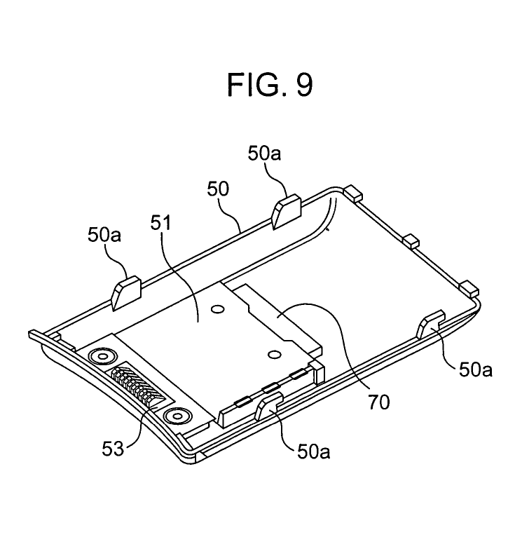

As shown in FIG. 9, the adapter 50 for the mobile phone has a holder 51 for holding the optionally additional functional component 70, and adapter engaging portions 50a (as the claimed joint portion) are provided with the adapter 50 to engage with the engage portions 24a of the mobile phone body. Each of the engaging portions 50a and corresponding one of the engaging portions 24a are engaged with each other to fix the adapter 50 to the mobile phone body, by moving the adapter downward to contact the casing 20, and subsequently moving rightward the adapter 50.

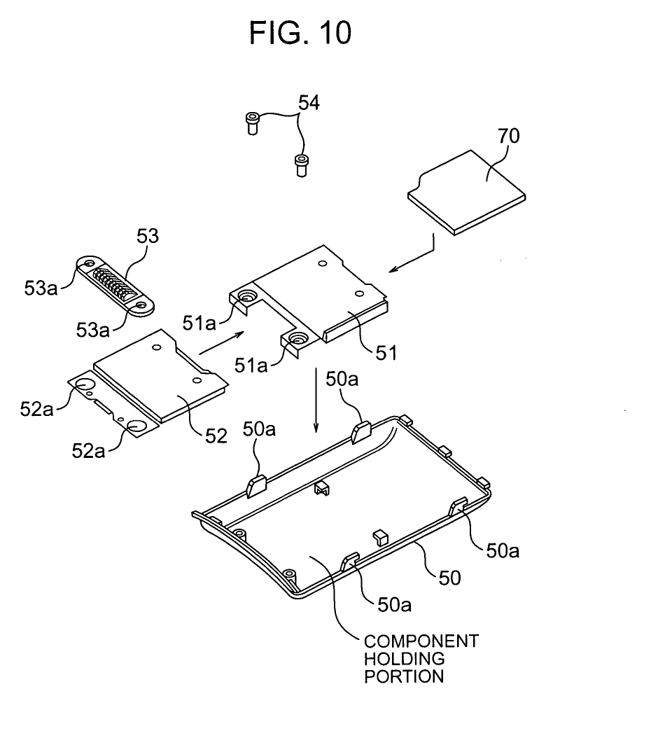

As shown in FIG. 10, a flexible electric connection substrate 52 is inserted into the holder 51 (as an example of the claimed component holding portion), holes 52a of the flexible electric connection substrate 52 are aligned with recesses 51a of the holder 51, holes 53a of adapter side connector 53 to be electrically connected to the optionally additional functional component 70 are aligned with recesses 51a of the holder 51, and the adapter side connector 53 is fixed to the casing 20 by screws 54 extending through the holes 51a, 52a and 53a.

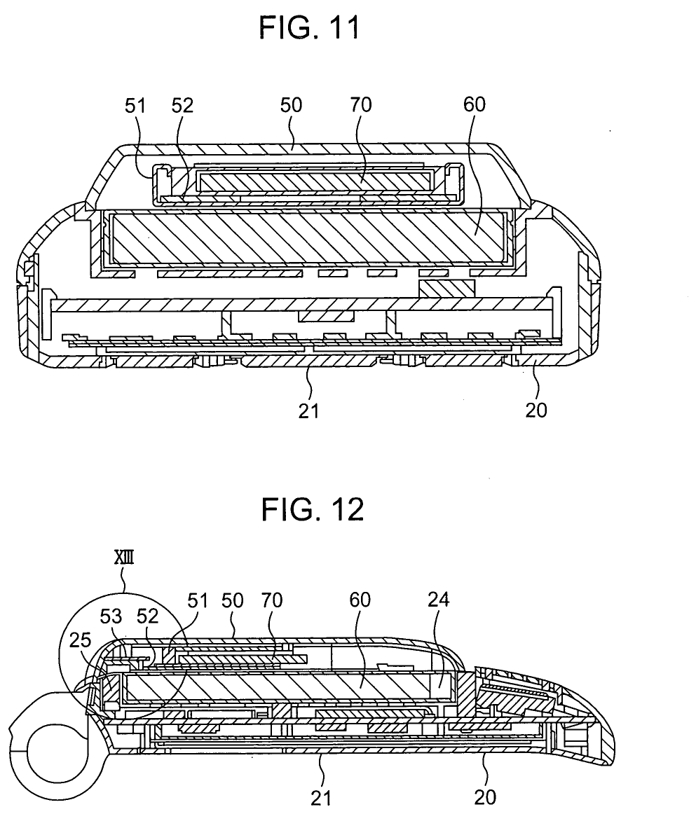

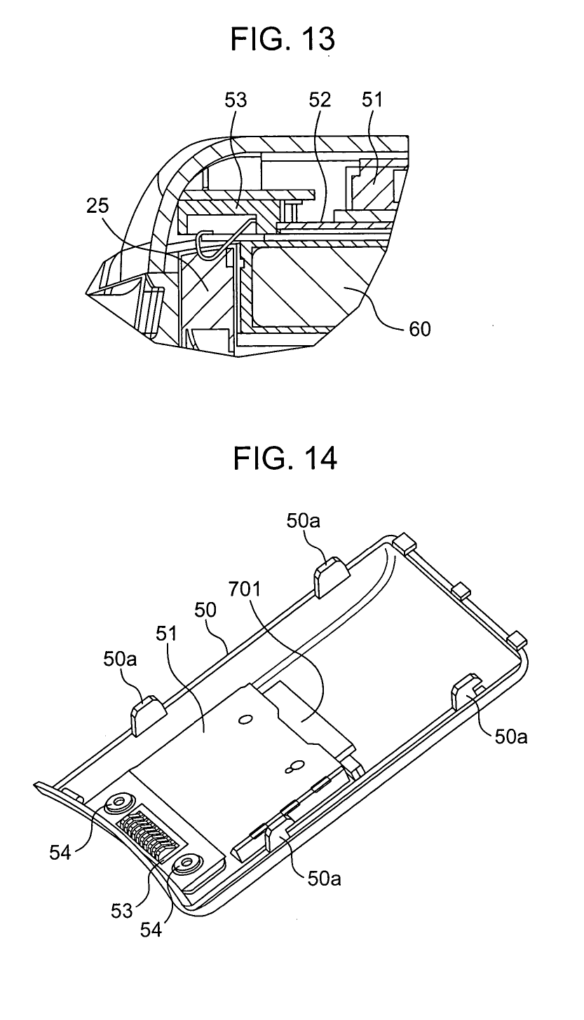

As shown in FIGS. 11-13, the adapter 50 for the mobile phone covers the battery 60 contained by the battery containing portion 24, and the adapter side connector 53 electrically connected to the optionally additional functional component 70 with the electric component mounted on the reverse side of the adapter 50 is electrically connected to the phone body side connector 26.

As shown in FIG. 14, a memory card 701 as the optionally additional functional component may be held by the holder 51. The mobile phone with the adapter 50 may be provided without the memory card 701 so that desired one of the memory card 701 is mounted in the adapter 50 afterward.

By replacing the battery cover 40 by the adapter 50 with the memory card 701 as the optionally additional functional component to be electrically connected to the phone body side connector 26 through the adapter side connector 53, a capacity of memory of the mobile phone is increased.

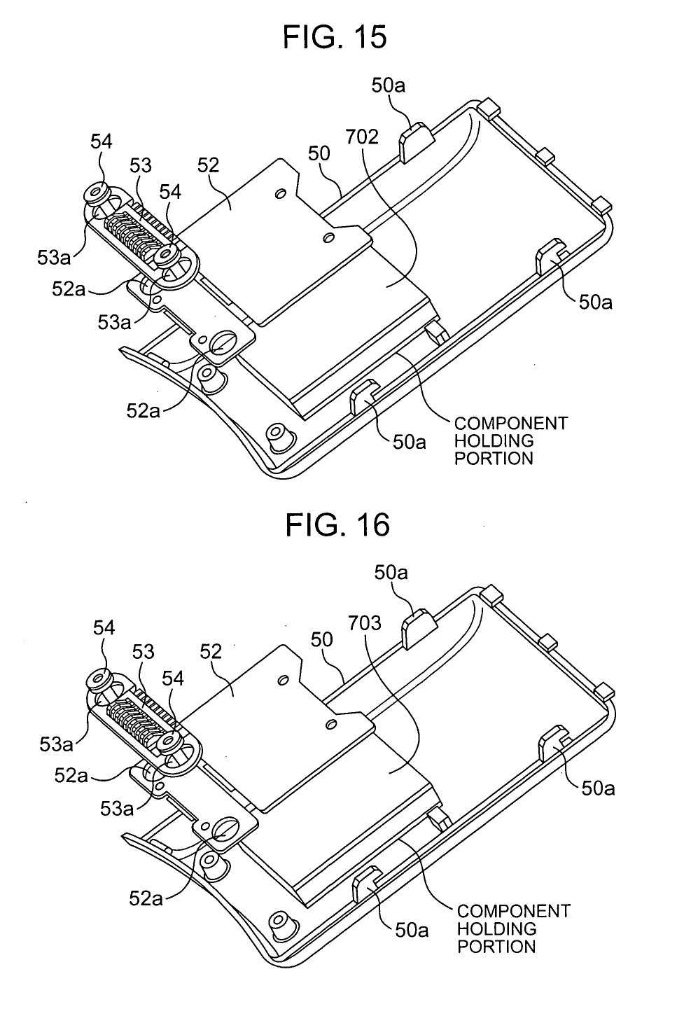

As shown in FIG. 15, the optionally additional functional component 702 may include a tuner circuit for band width other than the band width of mobile phone.

The optionally additional functional component 702 is mounted on the reverse side of the adapter 50, the flexible electric connection substrate 52 is mounted on the optionally additional functional component 702, the holes 52a of the flexible electric connection substrate 52 are aligned with the holes 53a of the adapter side connector 53 to be electrically connected to the optionally additional functional component 702, and the adapter side connector 53 is fixed to the casing 20 by screws 54 extending through the holes 52a and 53a.

By replacing the battery cover 40 by the adapter 50 with the optionally additional functional component 702 including the tuner circuit to be electrically connected to the phone body side connector 26 through the adapter side connector 53, the band width other than the band width of mobile phone is demodulated by the tuner circuit to be visualized on the indicating portion 11 or output from the speaker 23.

As shown in FIG. 16, the optionally additional functional component 703 may include a wireless communication circuit.

The optionally additional functional component 703 is mounted on the reverse side of the adapter 50, the flexible electric connection substrate 52 is mounted on the optionally additional functional component 703, the holes 52a of the flexible electric connection substrate 52 are aligned with the holes 53a of the adapter side connector 53 to be electrically connected to the optionally additional functional component 703, and the adapter side connector 53 is fixed to the casing 20 by screws 54 extending through the holes 52a and 53a.

By replacing the battery cover 40 by the adapter 50 with the optionally additional functional component 703 including the wireless communication circuit to be electrically connected to the phone body side connector 26 through the adapter side connector 53, a wireless communication signal is transmitted to the mobile phone.

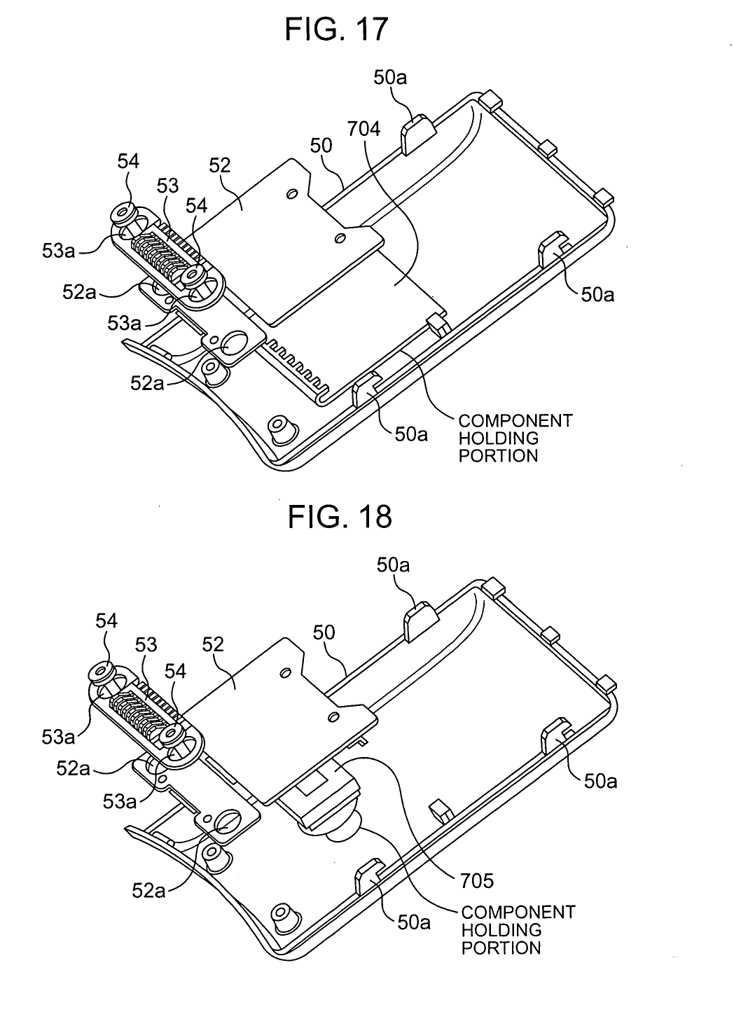

As shown in FIG. 17, the optionally additional functional component 704 may include an antenna extending over the reverse side of the adapter 50 as large as possible.

The optionally additional functional component 704 is mounted on the reverse side of the adapter 50, the flexible electric connection substrate 52 is mounted on the optionally additional functional component 703, the holes 52a of the flexible electric connection substrate 52 are aligned with the holes 53a of the adapter side connector 53 to be electrically connected to the optionally additional functional component 704, and the adapter side connector 53 is fixed to the casing 20 by the screws 54 extending through the holes 52a and 53a.

By replacing the battery cover 40 by the adapter 50 with the optionally additional functional component 704 including the antenna to be electrically connected to the phone body side connector 26 through the adapter side connector 53, an antenna gain is increased to improve a sensibility of the mobile phone for the wireless communication signal.

As shown in FIG. 18, the optionally additional functional component 705 may include a camera.

The optionally additional functional component 705 is mounted on the reverse side of the adapter 50, the flexible electric connection substrate 52 is mounted on the optionally additional functional component 703, the holes 52a of the flexible electric connection substrate 52 are aligned with the holes 53a of the adapter side connector 53 to be electrically connected to the optionally additional functional component 704, and the adapter side connector 53 is fixed to the casing 20 by the screws 54 extending through the holes 52a and 53a.

By replacing the battery cover 40 by the adapter 50 with the optionally additional functional component 705 including the camera to be electrically connected to the phone body side connector 26 through the adapter side connector 53, a size of the camera incorporated in the optionally additional functional component 705 may be larger than that of the camera incorporated in the mobile phone body to improve a sensibility, magnification or the like of a picture taken by the mobile phone.

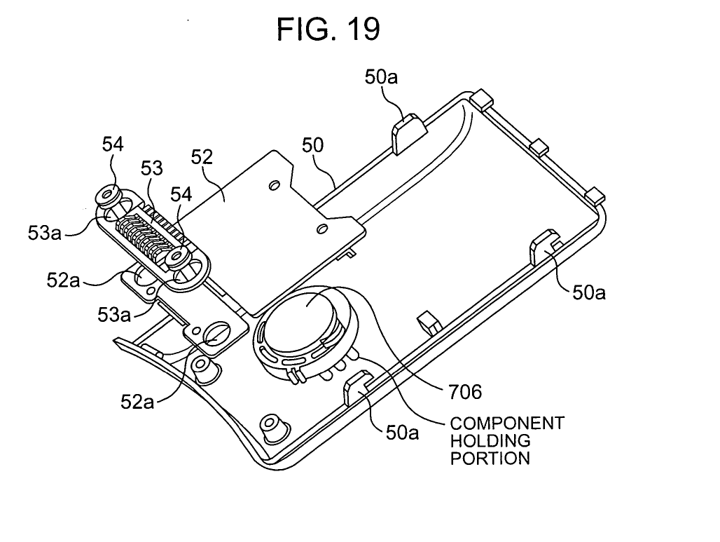

As shown in FIG. 19, the optionally additional functional component 706 may include a loudspeaker.

The optionally additional functional component 706 is mounted on the reverse side of the adapter 50, the flexible electric connection substrate 52 is mounted on the optionally additional functional component 703, the holes 52a of the flexible electric connection substrate 52 are aligned with the holes 53a of the adapter side connector 53 to be electrically-connected to the optionally additional functional component 706, and the adapter side connector 53 is fixed to the casing 20 by the screws 54 extending through the holes 52a and 53a.

By replacing the battery cover 40 by the adapter 50 with the optionally additional functional component 706 including the loudspeaker to be electrically connected to the phone body side connector 26 through the adapter side connector 53, a size of the loudspeaker incorporated in the optionally additional functional component 705 may be larger than that of the loud speaker incorporated in the mobile phone body to improve a sound quality or listen in stereo.

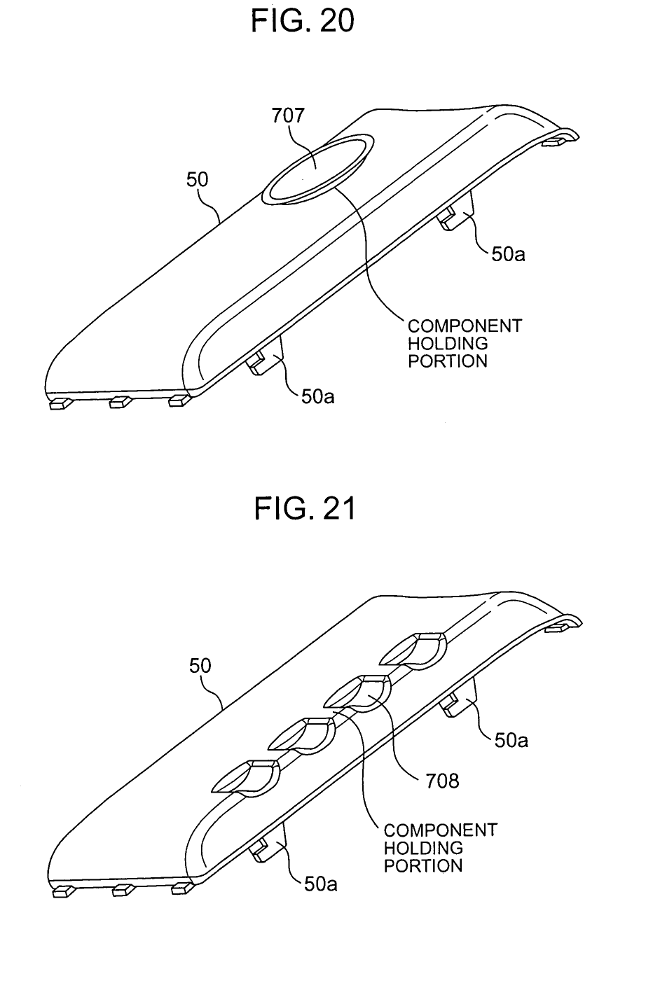

As shown in FIG. 20, the optionally additional functional component 707 without the electric component may include a suction cup.

By replacing the battery cover 40 by the adapter 50 with the optionally additional functional component 707 including the suction cup, the mobile phone can be fixed directly on a desired position, for example, a column.

As shown in FIG. 21, the optionally additional functional component 708 without the electric component may include recesses for finger grip, or a rubber coating on an outer surface of the adapter 50. The adapter 50 may be formed by a rubber for finger grip.

By replacing the battery cover 40 by the adapter 50 with the optionally additional functional component 708 for finger grip, the mobile phone can be held securely.

As shown in FIG. 22, the optionally additional functional component 709 without the electric component may include a photograph holder.

By replacing the battery cover 40 by the adapter 50 with the optionally additional functional component 709 including the photograph holder, a preferable photograph is visible by removing the adapter 50.

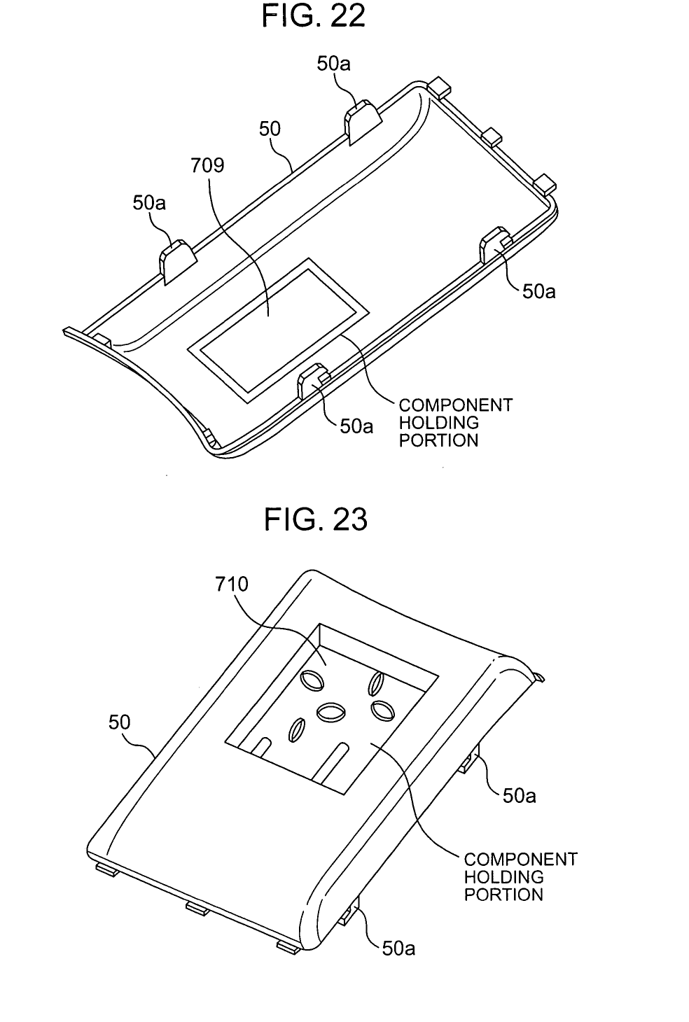

As shown in FIG. 23, the optionally additional functional component 710 without the electric component may include a game box embedded in the adapter.

By replacing the battery cover 40 by the adapter 50 with the optionally additional functional component 710 including the game box, a game can be played.

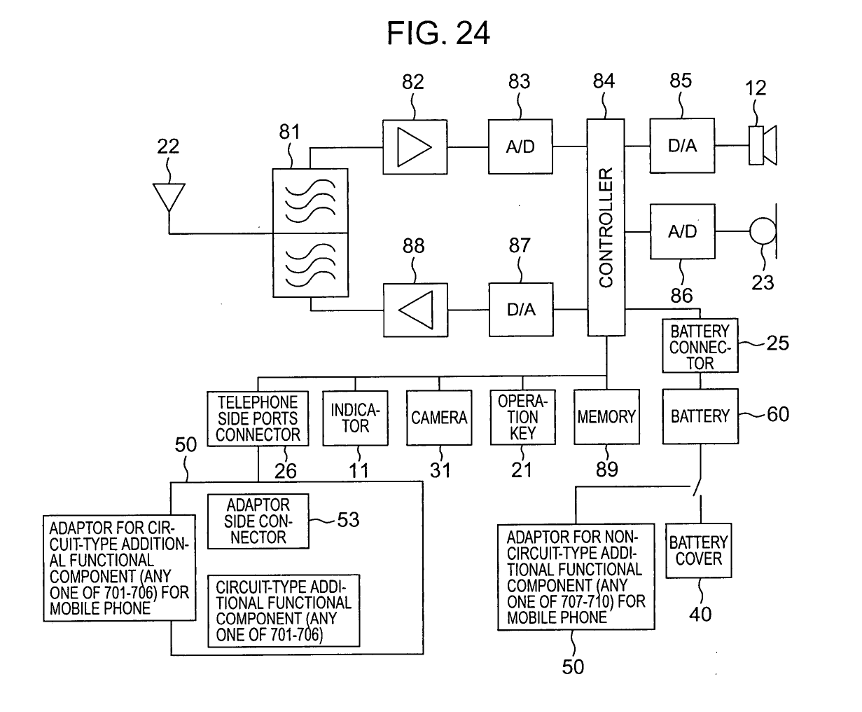

As shown in FIG. 24, a signal received by an antenna 22 is transmitted through a duplexer 81 to a receiver circuit 82, converted to a digital signal by an A/D converter 83, digitally remastered by a controller 84, and converted to an analog signal by a D/A converter 85 to be converted to a sound by a receiver 12. A sound signal input to a microphone 23 is converted by an A/D converter 86 to a digital signal, digitally remastered by the controller 84, converted to an analog signal by a D/A converter 87, and electrically amplified by a power circuit 88 to be transmitted from the antenna 22 through the duplexer 81. The signals to be received and transmitted are temporarily stored in a memory 89, and the signals are treated at once before being received and transmitted.

The battery as an electric power source for these operations supplies an electric power to the controller 84 through the battery connector 25.

The phone body side connector 26, indication portion 11, camera 31 and operation keys 21 are electrically connected to the controller 84.

The mobile phone of cheap type has the battery cover 40 without the optionally additional functional component.

The mobile phone of the invention includes the adapter 50 having one of the optionally additional functional components 701-706 with the electric component as shown in FIGS. 14-19 and the optionally additional functional components 707-710 without the electric component as shown in FIGS. 20-23.

Therefore, a consumer can obtain a desired function by purchasing the adapter 50 having desired one of the optionally additional functional components and mounting the purchased adapter 50 onto the mobile phone.

Further, the consumer can use selected one of the desired functions by exchanging the adapter 50 on the mobile phone as required.

The adapter 50 may be mounted at any position other than a position over the battery on the mobile phone.

By the invention, the mobile wireless communication device, the adapter for the mobile wireless communication device, and the method for selectively mounting the adapter for the mobile wireless communication device, in which a compact and light-weight structure of the mobile phone and/or adapter is maintained while making a selection range of the optionally additional functions wide, can be obtained.

It should be further understood by those skilled in the art that although the foregoing description has been made on embodiments of the invention, the invention is not limited thereto and various changes and modifications may be made without departing from the spirit of the invention and the scope of the appended claims.

1. An adapter for mounting an optionally-additional functional component onto a mobile wireless communication device, comprising,
a joint portion connectable to the mobile wireless communication device so that the adapter is attached through the joint portion to the mobile wireless communication device in a removable manner, and a component holding portion adapted to hold the optionally-additional functional component on the component holding portion.

2. An adapter according to claim 1, wherein the optionally-additional functional component includes at least one of a suction cup, a grip, a photograph holder and a game box.

3. An adapter according to claim 1, wherein the optionally-additional functional component includes an electric component to be electrically connected to the mobile wireless communication device.

4. An adapter according to claim 1, wherein the optionally-additional functional component is fixed to the component holding portion.

5. An adapter according to claim 1, wherein the optionally-additional functional component is connectable to the adapter so that the optionally-additional functional component is held on the component holding portion in a removable manner.

6. An adapter according to claim 1, wherein the optionally-additional functional component includes at least one of an electronic memory device, a tuner electric circuit, a wireless communication electric circuit, an antenna, a camera and a loudspeaker.

7. An adapter according to claim 1, wherein a battery for electrically energizing the mobile wireless communication device is mountable on the mobile wireless communication device, and at least a part of the battery is mountable between the adapter and the mobile wireless communication device as seen in a view direction perpendicular to a stacking direction in which the adapter and the mobile wireless communication device are stacked.

8. An adapter according to claim 1, wherein a battery for electrically energizing the mobile wireless communication device is mountable on the mobile wireless communication device, at least a part of the battery is mountable between the optionally-additional functional component and the mobile wireless communication device as seen in a view direction perpendicular to a stacking direction in which the adapter and the mobile wireless communication device are stacked.

9. An adapter according to claim 1, wherein the component holding portion is adapted to hold the optionally-additional functional component in such a manner that the optionally-additional functional component is mountable between the adapter and the mobile wireless communication device as seen in a view direction perpendicular to a stacking direction in which the adapter and the mobile wireless communication device are stacked.

10. An adapter according to claim 3, further comprising an electrically conductive contact terminal surface being electrically connectable to the electric component and adapted to contact the mobile wireless communication device so that the electric component is electrically connected through the electrically conductive terminal contact surface to the mobile wireless communication device in a separable manner.

11. An adapter according to claim 10, wherein a battery for electrically energizing the mobile wireless communication device is mountable on the mobile wireless communication device, at least a part of the battery is mountable between the adapter and the mobile wireless communication device as seen in a view direction perpendicular to a stacking direction in which the adapter and the mobile wireless communication device are stacked, and the electrically conductive contact terminal surface is arranged to be prevented from overlapping the battery as seen in the stacking direction.

12. An adapter according to claim 10, wherein a battery for electrically energizing the mobile wireless communication device is mountable on the mobile wireless communication device, at least a part of the battery is mountable between the optionally-additional functional component and the mobile wireless communication device as seen in a view direction perpendicular to a stacking direction in which the adapter and the mobile wireless communication device are stacked, and the electrically conductive contact terminal surface is arranged to be prevented from overlapping the battery as seen in the stacking direction.

13. A mobile wireless communication device comprising,
an adapter for mounting an optionally-additional functional component onto the mobile wireless communication device, including,
a joint portion connectable to the mobile wireless communication device so that the adapter is attached through the joint portion to the mobile wireless communication device in a removable manner, and a component holding portion adapted to hold the optionally-additional functional component on the component holding portion.

14. A mobile wireless communication device on which an adapter including an adapter joint portion connectable to the mobile wireless communication device and a component holding portion adapted to hold a optionally-additional functional component on the component holding portion is mountable, comprising,
a device joint portion connectable to the adapter joint portion so that the adapter is attached through the adapter and device joint portions to the mobile wireless communication device in a removable manner.

15. A method for selectively mounting onto a mobile wireless communication device an adapter being connectable to the mobile wireless communication device so that the adapter is attached to the mobile wireless communication device in a removable manner and including a component holding portion adapted to hold a optionally-additional functional component on the component holding portion, comprising the steps of
preparing a plurality of the adapters,
selecting one of the adapters, and
mounting the selected one of the adapters onto the mobile wireless communication device.
